(19) United States
(12) Patent Application Publication
(10) Pub. No.: US 2009/0079598 A1
(43) Pub. Date: Mar. 26, 2009

(54) SAMPLE RATE CONVERTER

(75) Inventors: Masanori Furuta, Mishima-shi (JP); Takafumi Yamaji, Yokohama-shi (JP); Takeshi Ueno, Kawasaki-shi (JP)

Correspondence Address: Charles N.J. Ruggiero, Esq.;Ohlandt, Greeley, Ruggiero & Perle, L.L.P., 10th Floor, One Landmark Square, Stamford, CT, 06901-2682, US

(73) Assignee: Kabushiki Kaisha Toshiba

(21) Appl. No.: 12/057,647

(22) Filed: Mar. 28, 2008

(30) Foreign Application Priority Data
Sep. 20, 2007 (JP) 2007-244322

(51) Int. Cl. H03M 7/00

(52) U.S. Cl. 341/61

(57) ABSTRACT

The sample rate converter includes a synthesizing unit which synthesizes an input signal sampled with frequency fs with a feedback signal of the frequency fs, in a frequency band from 0 to fs/N (where N indicates a natural number), with a gain greater than at least 1, to generate a synthesized signal, a downsampler which downsamples the synthesized signal to obtain an output signal of sample rate fs/N, and an upsampler which upsamples the output signal to generate the feedback signal.

### CROSS-REFERENCE TO RELATED APPLICATIONS

This application is based upon and claims the benefit of priority from prior Japanese Patent Application No. 2007-244322, filed Sep. 20, 2007, the entire contents of which are incorporated herein by reference.

### BACKGROUND OF THE INVENTION

1. Field of the Invention

The present invention relates to a sample rate converter capable of converting a sample rate.

2. Description of the Related Art

When, for example, a high-speed digital signal output of an oversampling-type A/D converter is downsampled, a problem arises that alias components of quantization noise are generated in a desired signal band and the signal deterioration is thereby caused. To solve this problem in the prior art, the alias components have been removed and downsampling has been executed by employing a decimation filter. As a decimation filter employed in this situation, a Finite Impulse Response (FIR) filter capable of obtaining characteristics including a phase linearity has been frequently employed and, especially, a sinc-type filter has been employed (cf., for example, Jpn. Pat. Appln. KOKAI Publication No. 10-209815 and U.S. Pat. No. 6,501,406).

However, since the sinc-type filter has a comb-shaped frequency characteristic, the alias components are increased, an ability to remove the alias components is not only lowered but the signal amplitude is also deteriorated as the desired signal becomes a broadband. For this reason, in a system which needs to have a high alias signal removing rate, a high-order decimation filter is required and the hardware is large.

As means for increasing the ability to remove the alias, employing a low-pass filter to form a decimation filter is effective. Especially, implement employing the Infinite Impulse Response (IIR) filter is an effective technique as means for designing a high-order filter with small hardware. In this system, however, the phase linearity cannot be assured due to the characteristics of the filter.

In the conventional sample rate converter, obtaining a sufficient suppression characteristic against an unnecessary signal while satisfying the flat amplitude characteristic and phase linearity in a desired signal band is difficult, and problems arise that the hardware becomes large to obtain desired characteristics and that the phase characteristic becomes nonflat.

An object of the present invention is to provide a sample rate converter capable of obtaining the flat amplitude characteristic and flat phase characteristic in a desired signal band with a comparatively small hardware amount, and of obtaining a necessary alias signal removing ability.

### BRIEF SUMMARY OF THE INVENTION

An aspect of the present invention provides a sample rate converter which converts a sample rate by filtering an input signal sampled with frequency fs by a feedback alias. The sample rate converter comprises a synthesizing unit which synthesizes an input signal sampled with frequency fs with a feedback signal of the frequency fs, in a frequency band from 0 to fs/N (where N indicates a natural number), with a gain greater than at least 1, to generate a synthesized signal, a downsampler which downsamples the synthesized signal to obtain an output signal of sample rate fs/N, and an upsampler which upsamples the output signal to generate the feedback signal.

### BRIEF DESCRIPTION OF THE SEVERAL VIEWS OF THE DRAWING

FIG. 1 is a block diagram showing a configuration of a sample rate converter according to a first embodiment;

FIG. 2 is a block diagram showing a configuration of a negative feedback circuit;

FIG. 3 is a block diagram showing a configuration of the sample rate converter shown in FIG. 1;

FIG. 4 is a graph showing a frequency characteristic of a filter circuit in the sample rate converter shown in FIG. 1;

FIG. 5 is a graph showing a frequency characteristic of the filter circuit in the sample rate converter shown in FIG. 1;

FIG. 6 is a graph showing a comparison between a power level of a alias component and a power level of a desired signal at the sample rate converter shown in FIG. 1;

FIG. 7 is a block diagram showing a configuration example of the sample rate converter shown in FIG. 1;

FIG. 8 is a graph showing a comparison between a power level of a alias component and a power level of a desired signal at the sample rate converter shown in FIG. 7;

FIG. 9 is a block diagram showing a configuration example of the sample rate converter shown in FIG. 1;

FIG. 10 is a graph showing a comparison between a power level of a alias component and a power level of a desired signal at the sample rate converter shown in FIG. 9;

FIG. 11 is a block diagram showing a configuration example of the sample rate converter shown in FIG. 1;

FIG. 12 is a block diagram showing a configuration of a sample rate converter according to a second embodiment;

FIG. 13 is a block diagram showing a configuration example of the sample rate converter shown in FIG. 12;

FIG. 14 is a block diagram showing a configuration of a sample rate converter according to a third embodiment;

FIG. 15 is a block diagram showing a configuration of a sample rate converter according to a fourth embodiment;

FIG. 16 is a block diagram showing a configuration of a modified example of the sample rate converter according to the fourth embodiment;

FIG. 17 is a block diagram showing a modified configuration of the sample rate converter according to the embodiment; and

FIG. 18 is a table showing an effect of the modified example shown in FIG. 17.

### DETAILED DESCRIPTION OF THE INVENTION

### First Embodiment

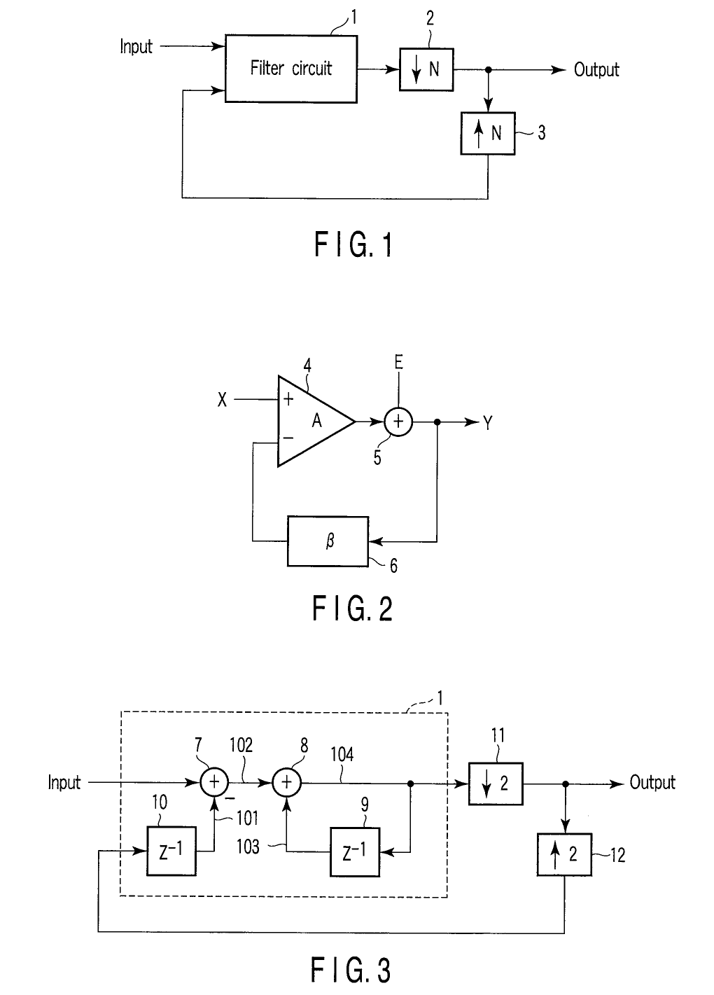

A sample rate converter according to a first embodiment of the present invention will be explained below with reference to the accompanying drawings. The sample rate converter shown in FIG. 1 comprises a filter circuit 1, a downsampler circuit 2 and an upsampler circuit 3, which form a feedback loop circuit.

The filter circuit 1 is a linear filter circuit which inputs an input signal sampled with frequency fs and a feedback signal output from the upsampler circuit 3, and which outputs a synthesized signal of the input signal and the feedback signal. More specifically, the filter circuit 1 has a function of supplying a gain greater than at least 1 to two input signals in desired signal band fs/N and outputting a synthesized signal of the input signals at a sample rate of the frequency fs. A gain smaller than a gain in a desired signal band is supplied to a signal band inverted in the desired signal band at the time of downsampling. Therefore, a signal sequence of the sample rate of the frequency fs is output from the filter circuit 1 as the synthesized signal.

The downsampler circuit 2 downsamples the sample rate of the synthesized signal to fs/N by executing downsampling to decimate number N−1 of data elements per N samples (where N represents an integer equal to or greater than 2), for the signal sequence of the sample rate of the frequency fs output from the filter circuit 1, and outputs the downsampled signal to the upsampler circuit 3 and a circuit of a subsequent stage (not shown).

The upsampler circuit 3 raises again the sample rate reduced by the downsampler circuit 2 to fs by executing upsampling to insert number N−1 of zero data elements between the sample value data, for the downsampled signal of sample rate fs/N, and outputs the signal to the filter circuit 1 as a feedback signal.

In other words, the sample rate converter comprises the filter circuit 1, the downsampler circuit 2 and the upsampler circuit 3, these circuits form the feedback loop circuit, the filter circuit 1 synthesizes the input signal and the feedback signal by supplying a gain greater than 1 to each of the signals in the band fs/N of the desired signal obtained by downsampling, and the synthesized signal is downsampled by the downsampler circuit 2 and then output.

For this reason, a phase linearity and a substantially flat amplitude characteristic hardly having deterioration in the amplitude can be obtained as a desired signal subjected to rate conversion. In addition, the sample rate converter can effectively delete the only alias component by the feedback effect. The alias component can be thereby removed comparatively easily in a high order while maintaining a substantially flat amplitude characteristic.

The effect of the sample rate conversion will be explained here with reference to a negative feedback circuit shown in FIG. 2. FIG. 2 shows a concept of the feedback loop circuit of the sample rate converter shown in FIG. 1. If the negative feedback circuit has an input circuit represented by X, an output signal represented by Y, a gain represented by A, a feedback factor represented by β, and an error mixed in the circuit represented by E, the negative feedback circuit comprises an amplifier circuit 4 which inputs the input circuit X and the feedback signal and which outputs a A-fold amplified signal, an adder 5 which outputs an addition signal obtained by summing up the amplified signal and the error E, and a factor multiplier 6 which multiplies the addition signal by the feedback factor β. The amplifier circuit 4, the adder 5 and the factor multiplier 6 form a feedback loop to output the addition signal as the feedback signal.

In this circuit, a relation between the input and the output is represented below in formula (1).

$$Y = \frac{A}{1 + A β} X + \frac{1}{1 + A β} E \qquad ( 1 )$$

If it is assumed that the gain A of the amplifier circuit 4 is sufficiently high as compared with 1 and the feedback factor is 1, the formula (1) is modified to formula (2).

$$Y ≅ X + \frac{1}{A} E \qquad ( 2 )$$

The formula (2) indicates that an influence of the error E to the output becomes increased 1/A-fold due to the gain A of the amplifier circuit 4. Thus, the negative feedback circuit has the feedback effect of avoiding most influence of the error E mixed in the output of the amplifier circuit 4 and outputting the input signal which is hardly deteriorated, if the gain A of the amplifier circuit 4 is sufficiently high as compared with 1.

The sample rate converter shown in FIG. 1 takes advantage of the feedback effect. A component corresponding to the error E in FIG. 2 is equivalent to the alias component generated at the downsampling time in FIG. 1. For this reason, the sample rate converter can output a desired signal which is downsampled without sufficiently receiving the influence of the alias component, by setting a sufficiently high gain as compared with 1 in the desired signal band in the filter circuit 1, to implement the characteristic of the linear filter.

Therefore, substantially flat amplitude characteristic and phase linearity that hardly include the deterioration in amplitude can be obtained as the desired signal subjected to the rate conversion, by employing the sample rate converter. In addition, the sample rate converter can effectively delete the alias component, by the feedback effect. The alias component can be thereby removed comparatively easily in a high order while maintaining a substantially flat amplitude characteristic.

The sample rate converter can employ, for example, an IIR-type filter which has a problem of phase distortion but can be designed in a high order with a small circuit area if the filter has the above characteristic. The circuit area and the power consumption can be thereby reduced as compared with the prior art.

Next, a more specified configuration example 1 of the sample rate converter according to the first embodiment will be described. FIG. 3 shows the configuration example 1. In this example, the filter circuit 1 comprises an adder 7, an adder 8, a delay unit 9 and a delay unit 10. In addition, the filter circuit 1 employs a downsampler circuit 11 which sets the number of frequency division of the downsampler circuit 2 at 2, and an upsampler circuit 12 which sets a multiple number of the upsampler circuit 3 at 2.

The adder 7 subtracts a delay signal 101 obtained by delaying the feedback signal from the upsampler circuit 12 by the delay unit 10, from the input signal sampled at the frequency fs, and outputs the subtraction result as a synthesized signal 102.

The adder 8 adds the synthesized signal 102 and a delay signal 103 obtained by delaying a synthesized signal 104 to be output from the adder 8 by the delay unit 10, and outputs the addition result as the synthesized signal 104. The delay unit 9 and the delay unit 10 delay the input signal by one sample.

The downsampler circuit 11 inputs the synthesized signal 104 which is the output of the filter circuit 1, and downsamples the input signal to decimate the signal sequence such that the sample rate becomes fs/2.

The upsampler circuit 12 inserts zero data into the signal downsampled by the downsampler circuit 11, upsamples the signal to double sample rate fs, and outputs the upsampled signal to the delay unit 10 as a feedback signal.

By thus forming the sample rate converter, the alias component is generated in the output signal at the time of downsampling in the downsampler circuit 11. The alias component is suppressed in accordance with the characteristic of the filter circuit 1. The sample rate converter shown in FIG. 3 can remove the alias component while making the desired signal characteristic substantially flat, by taking advantage of the characteristic of a primary integrator inserting a pole into a DC point as the characteristic of the filter circuit 1.

A transfer function of the filter circuit 1 in the sample rate converter shown in FIG. 3 can be represented in formula (3).

$$H ( z ) = \frac{1}{1 - {z}^{- 1}} \qquad ( 3 )$$

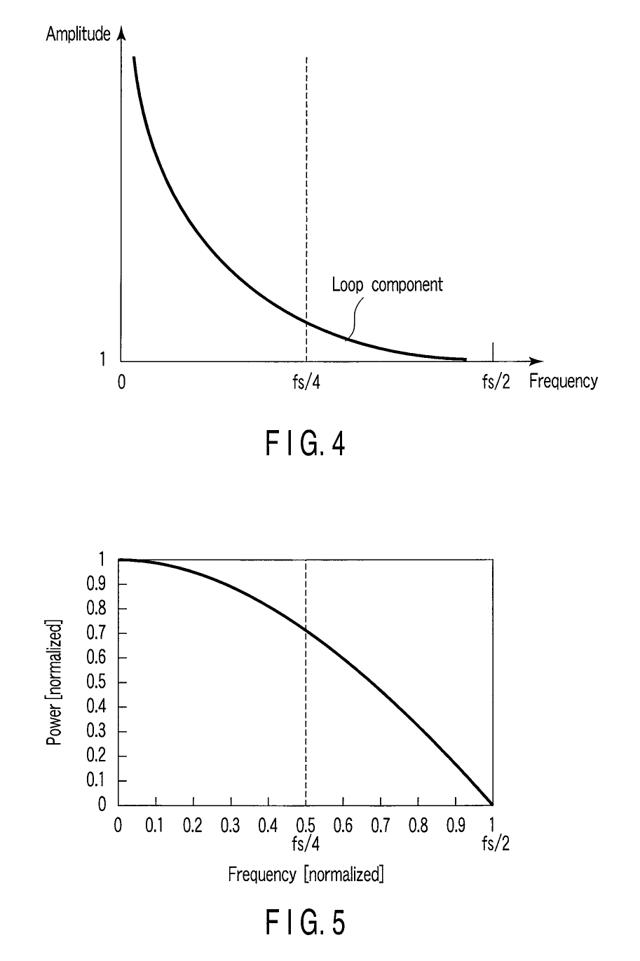

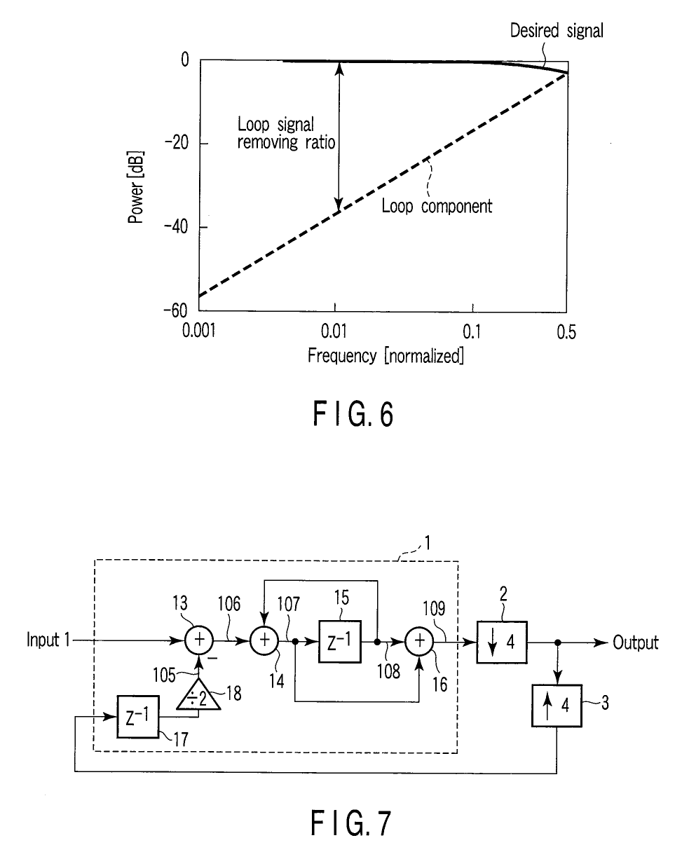

The transfer function has a frequency characteristic having an infinite gain in the vicinity of the DC as shown in FIG. 4. To understand the frequency characteristic of the downsampler circuit shown in FIG. 3 having the frequency characteristic of the filter circuit shown in FIG. 4, a result of observation of the frequency characteristic of the feedback signal in the downsampler circuit is shown in FIG. 5. Since the sample rate of the feedback signal is fs, a frequency axis in the characteristic shown in FIG. 5 represents up to a Nyquist rate (fs/2). As shown by a result of FIG. 5, the amplitude characteristic of 1 at the desired signal or 0 at the Nyquist rate can be obtained by using the filter characteristic of FIG. 4. Actually, the downsampled signal shown in FIG. 6 is output. The downsampled signal has a characteristic that the frequency characteristic is inverted in the desired signal band at fs/4.

Therefore, as shown in FIG. 6, the alias component in the desired signal band can be restricted on the basis of the feedback effect, in view of the characteristic of the filter circuit 1. When the desired signal band is at 1% of fs, an alias signal removing ratio of 25 [dB] is implemented.

Next, a more specified configuration example 2 of the sample rate converter according to the first embodiment will be described. FIG. 7 shows the configuration example 2. In this example, the number of frequency division of the downsampler circuit 2 is set at 4 and the multiple number of the upsampler circuit 3 is set at 4. The filter circuit 1 comprises an adder 13, an adder 14, a delay unit 15, an adder 16, a delay unit 17 and a divider 18.

The adder 13 subtracts a signal 105 obtained by delaying the feedback signal from the upsampler circuit 3 by the delay unit 17 and dividing the signal amplitude by the divider 18, from the input signal sampled at the frequency fs, and outputs the subtraction result as a synthesized signal 106.

The adder 14 adds the synthesized signal 106 and a delay signal 108 obtained by delaying a synthesized signal 107 to be output from the adder 14 by the delay unit 15, and outputs the addition result as the synthesized signal 107. The delay unit 15 and the delay unit 17 delay the input signal by one sample.

The adder 16 adds the synthesized signal 107 and the delay signal 108 and outputs the addition result as a synthesized signal 109.

The downsampler circuit 2 inputs the synthesized signal 109 which is the output of the filter circuit 1, and downsamples the input signal to decimate the signal sequence such that the sample rate becomes fs/4.

The upsampler circuit 3 inserts zero data into the signal downsampled by the downsampler circuit 2, upsamples the signal to four-fold sample rate fs, and outputs the upsampled signal to the delay unit 17 as a feedback signal.

The sample rate converter implements a transfer function represented below in formula (4), by adding the adder 16 to the filter circuit 1 shown in FIG. 3 and thereby adding the delayed signal 108 delayed by the delay unit 15 to the synthesized signal 107 output from the adder 14.

$$H ( z ) = \frac{1 + {z}^{- 1}}{1 - {z}^{- 1}} \qquad ( 4 )$$

The filter circuit 1 having such a configuration can obtain an infinite gain in the vicinity of the DC and has the frequency characteristic which becomes 0 with the frequency of fs/2, by inserting zero point into the DC point with the pole and the frequency of fs/2. The alias component in the desired signal band can be restricted on the basis of the feedback effect while preliminarily reducing the alias component in the characteristic of the linear filter, and the alias component can be removed in terms of the quadratic characteristic while obtaining a substantially flat, desired signal characteristic similarly to the sample rate converter shown in FIG. 3.

Since the filter circuit 1 can obtain the quadratic characteristic as the alias component removing ability, the circuit area can be substantially reduced to a half as compared with the conventional sinc-type filter when the downsampling ratio is 4. For this reason, the sample rate converter using the filter circuit 1 as shown in FIG. 7 has the alias component removing ability enhanced as compared with the sample rate converter as shown in FIG. 3, by making a few amendments to the conventional circuitry.

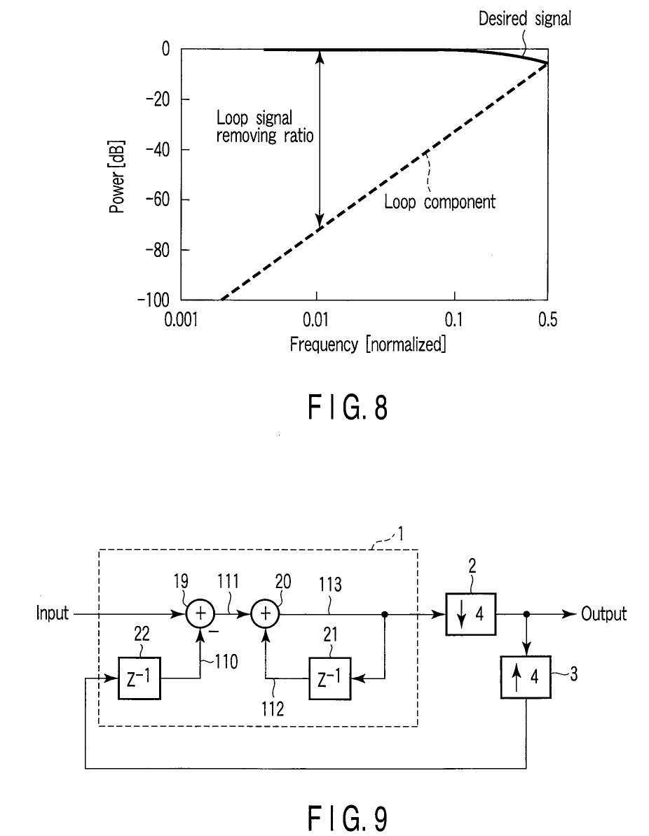

FIG. 8 shows a simulation result. In the filter circuit 1 shown in FIG. 7, when the desired signal band is at 1% of fs, the alias signal removing ratio of 73 [dB] can be implemented, and the alias signal removing ratio can be enhanced by approximately 50 [dB] as compared with the sample rate converter shown in FIG. 3.

Next, a more specified configuration example 3 of the sample rate converter according to the first embodiment will be described. FIG. 9 shows the configuration example 3. In this example, the filter circuit 1 comprises an adder 19, an adder 20, a delay unit 21, and a delay unit 22. The number of frequency division of the downsampler circuit 2 is set at 4 and the multiple number of the upsampler circuit 3 is set at 4.

The adder 19 subtracts a signal 110 obtained by delaying the feedback signal from the upsampler circuit 3 by the delay unit 22, from the input signal sampled at the frequency fs, and outputs the subtraction result as a synthesized signal 111.

The adder 20 adds the synthesized signal 111 and a delay signal 112 obtained by delaying a synthesized signal 113 to be output from the adder 20 by the delay unit 21, and outputs the addition result as the synthesized signal 113. The delay unit 21 and the delay unit 22 delay the input signal by one sample.

The downsampler circuit 2 inputs the synthesized signal 113 which is the output of the filter circuit 1, and downsamples the input signal to decimate the signal sequence such that the sample rate becomes fs/4.

The upsampler circuit 3 inserts zero data into the signal downsampled by the downsampler circuit 2, upsamples the signal to four-fold sample rate fs, and outputs the upsampled signal to the delay unit 21 as a feedback signal.

By thus forming the sample rate converter, the alias component is generated in the output signal at the time of downsampling in the downsampler circuit 2. The alias component is suppressed in accordance with the characteristic of the filter circuit 1. The sample rate converter shown in FIG. 9 can remove the alias component while making the desired signal characteristic substantially flat, by taking advantage of the characteristic of a primary integrator inserting a pole into a DC point as the characteristic of the filter circuit 1.

In addition, since the number of frequency division of downsampling is increased from 2 to 4 as compared with the sample rate converter shown in FIG. 3, the frequency becomes 0, i.e. the alias frequency to the DC component becomes fs/2 and fs/4, and the alias component is increased as compared with a case where the number of frequency division is 2. To avoid this, in the prior art, the decimation filter needs to be designed such that the zero point is present at the frequency of fs/2 and fs/4 when the number of frequency division is 4. In other words, change in the design of the filter is required as the number of frequency division is increased, in the conventional decimation filter.

On the other hand, in the sample rate converter shown in FIG. 9, the circuit architecture does not need to be changed in accordance with the number of frequency division of the downsampler circuit and the design of circuit is facilitated since the signal component folding in the desired signal band can be reduced even if the number of frequency division of downsampling is increased.

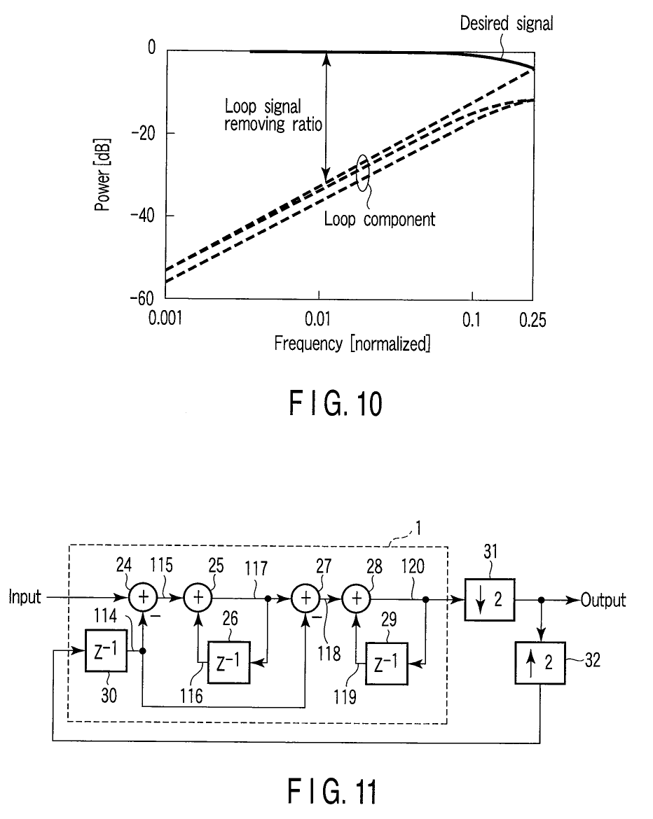

FIG. 10 shows a simulation result of the sample rate converter shown in FIG. 9. In the sample rate converter, when the desired signal band is at 1% of fs, the alias signal removing ratio of 24 [dB] can be implemented, and substantially the same alias signal removing ratio as the sample rate converter shown in FIG. 3 can be implemented even when the ratio of frequency division is increased.

Next, a more specified configuration example 4 of the sample rate converter according to the first embodiment will be described. FIG. 11 shows the configuration example 4. In this example, the filter circuit 1 comprises an adder 24, an adder 25, a delay unit 26, an adder 27, an adder 28, a delay unit 29 and a delay unit 30. In addition, a downsampler circuit 31 in which the number of frequency division of the downsampler circuit 2 is set at 2 is employed and an upsampler circuit 32 in which the multiple number of the upsampler circuit 3 is set at 2 is also employed.

The adder 24 subtracts a signal 114 obtained by delaying the feedback signal from the upsampler circuit 32 by the delay unit 25, from the input signal sampled at the frequency fs, and outputs the subtraction result as a synthesized signal 115.

The adder 25 adds the synthesized signal 114 and a delay signal 116 obtained by delaying a synthesized signal 117 to be output from the adder 25 by the delay unit 26, and outputs the addition result as the synthesized signal 117.

The adder 27 subtracts the delay signal 114 delayed by the delay unit 30 from the synthesized signal 117, and outputs the subtraction result as a synthesized signal 118.

The adder 28 adds the synthesized signal 118 and a delay signal 119 obtained by delaying a synthesized signal 120 to be output from the adder 28 by the delay unit 29, and outputs the addition result as the synthesized signal 120. The delay unit 29 and the delay unit 30 delay the input signal by one sample.

The downsampler circuit 31 inputs the synthesized signal 120 which is the output of the filter circuit 1, and downsamples the input signal to decimate the signal sequence such that the sample rate becomes fs/2.

The upsampler circuit 32 inserts zero data into the signal downsampled by the downsampler circuit 31, upsamples the signal to double sample rate fs, and outputs the upsampled signal to the delay unit 30 as a feedback signal.

By thus forming the sample rate converter, the alias component is generated in the output signal at the time of downsampling in the downsampler circuit 31. The alias component is suppressed in accordance with the characteristic of the filter circuit 1. The sample rate converter shown in FIG. 11 can remove the alias component while making the desired signal characteristic substantially flat, by taking advantage of the characteristic of an integrator in which a pole is inserted into a DC point and the order is primary as the characteristic of the filter circuit 1.

In addition, since the order of the transfer function is made higher as compared with the sample rate converter shown in FIG. 3, the alias component removing ability can be enhanced as compared with the sample rate converter shown in FIG. 3. For simple explanation, the order of the filter circuit shown in FIG. 11 is quadratic. However, when the order is quadratic or higher, the effect of enhancing the alias component removing ability can be obtained.

### Second Embodiment

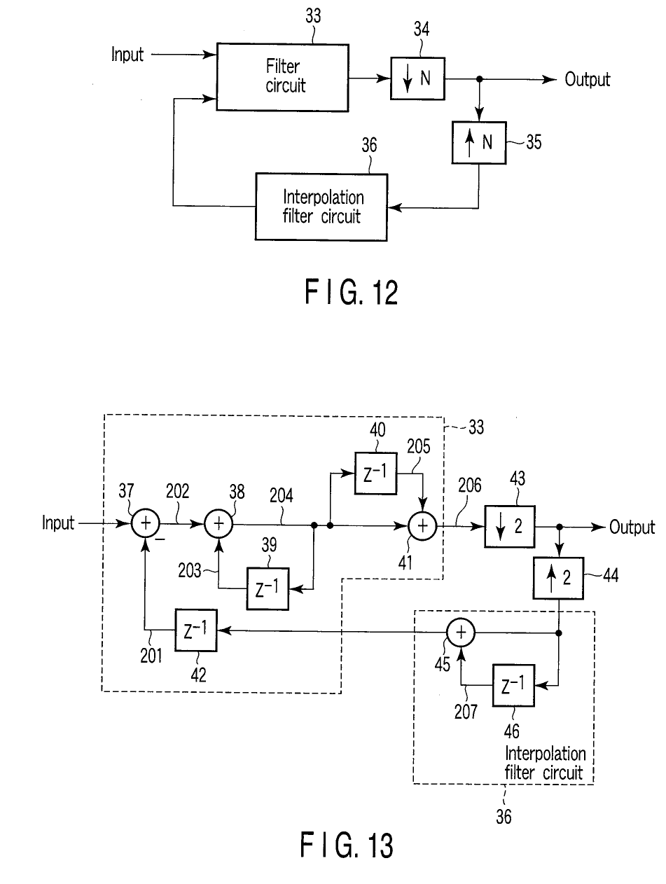

A sample rate converter according to a second embodiment of the present invention will be explained. The sample rate converter shown in FIG. 12 comprises a filter circuit 33, a downsampler circuit 34, an upsampler circuit 35 and an interpolation filter circuit 36, which form a feedback loop circuit.

The filter circuit 33 is a linear filter circuit which inputs an input signal sampled with frequency fs and also inputs a feedback signal output from the upsampler circuit 35 via the interpolation filter circuit 36, and which outputs a synthesized signal of the input signal and the feedback signal. More specifically, the filter circuit 33 has a function of supplying a gain greater than at least 1 to two input signals in a desired signal band and outputting a synthesized signal of the input signals at a sample rate of the frequency fs. Therefore, a signal sequence of the sample rate of the frequency fs is output from the filter circuit 33 as the synthesized signal.

The downsampler circuit 34 downsamples the sample rate of the synthesized signal to fs/N by executing downsampling to decimate number N−1 of data elements per N samples (where N represents an integer equal to or greater than 2), for the signal sequence of the sample rate of the frequency fs output from the filter circuit 33, and outputs the downsampled signal to the upsampler circuit 35 and a circuit of a subsequent stage (not shown).

The upsampler circuit 35 raises again the sample rate reduced by the downsampler circuit 2 to fs by executing upsampling to insert number N−1 of zero data elements between the sample value data, for the downsampled signal of sample rate fs/N, and outputs the signal to the interpolation filter circuit 36 as a feedback signal.

The interpolation filter circuit 36 comprises, for example, a FIR filter, executes filtering by multiplying the output of the sample rate fs output from the upsampler circuit 35 by a window function and outputs the filtering result to the filter 33 as a feedback signal.

In the sample rate converter having the above-described configuration, too, the characteristic of the linear filter can be implemented on the basis of the feedback effect and the desired signal downsampled without substantially receiving an influence of the alias component can be output, by setting a sufficiently high gain as compared with 1 in the desired signal band in the filter circuit 33.

Therefore, substantially flat amplitude characteristic and phase linearity that hardly include the deterioration in amplitude can be obtained as the rate-converted desired signal by employing the above-described sample rate converter. The sample rate converter can effectively remove the only alias component by the feedback effect. The alias component can be thereby removed comparatively easily in a high order while maintaining a substantially flat amplitude characteristic.

In addition, in the sample rate converter shown in FIG. 12, the interpolation filter circuit 36 is provided on the feedback loop. The interpolation filter circuit 36 corrects the amplitude characteristic reduced or distorted by the filter circuit 33 by multiplying the amplitude characteristic of the feedback signal by the window function. The amplitude characteristic of the desired signal can be thereby improved to be flat.

The sample rate converter can use an IIR filter which has a problem of phase distortion but is capable of designing a high-order filter with a small circuit area if it satisfies the above-described characteristic. The circuit area and the power consumption can be thereby reduced as compared with the prior art.

Next, a more specified configuration example of the sample rate converter according to the second embodiment will be described. FIG. 13 shows the configuration example. In this example, the filter circuit 33 comprises an adder 37, an adder 38, a delay unit 39, a delay unit 40, an adder 41 and a delay unit 42. In addition, the filter circuit 33 employs a downsampler circuit 43 which sets the number of frequency division of the downsampler circuit 34 at 2, and an upsampler circuit 42 which sets the multiple number of the upsampler circuit 35 at 2.

The adder 37 subtracts a delay signal 201 obtained by delaying the feedback signal from the upsampler circuit 44 by the delay unit 42 via the interpolation filter circuit 36, from the input signal sampled at the frequency fs, and outputs the subtraction result as a synthesized signal 202.

The adder 38 adds the synthesized signal 202 and a delay signal 203 obtained by delaying a synthesized signal 204 to be output from the adder 38 by the delay unit 39, and outputs the addition result as the synthesized signal 204.

The adder 41 adds the synthesized signal 204 and a delay signal 205 obtained by delaying the synthesized signal 204 by the delay unit 40, and outputs the addition result as the synthesized signal 206. The delay unit 39, the delay circuit 40 and the delay unit 42 delay the input signal by one sample. The output of the delay unit 39 may be used as the delay signal 205 by the adder 41 without using the delay unit 40.

The downsampler circuit 43 inputs the synthesized signal 206 which is the output of the filter circuit 33, and downsamples the input signal to decimate the signal sequence such that the sample rate becomes fs/2.

The upsampler circuit 44 inserts zero data into the signal downsampled by the downsampler circuit 43, upsamples the signal to double sample rate fs.

The interpolation filter circuit 36 comprises an adder 45 and a delay unit 46. The adder 45 adds the output of the sample rate fs output from the upsampler circuit 44 and a delay signal 207 obtained by delaying the output by the delay unit 46, and outputs the addition result to the delay unit 42 as a feedback signal.

By thus forming the sample rate converter, the alias component is generated in the output signal at the time of downsampling in the downsampler circuit 43. The alias component is suppressed in accordance with the characteristic of the filter circuit 33. The filter circuit 33 is a filter circuit which has a bilinear frequency characteristic having a pole in the vicinity of the DC and a zero point at the Nyquist frequency of the sampling frequency fs. Therefore, the characteristic of a primary integrator inserting the pole into the DC point can be obtained as the characteristic of the filter circuit 33, and the alias component can be removed while making the desired signal characteristic substantially flat.

In addition, in the sample rate converter having the above-described configuration, since the interpolation filter circuit 36 is provided in the feedback loop, amplitude attenuation in a high-pass portion can be improved. The order of the filter circuit 33 shown in FIG. 13 is set to be quadratic for simple explanation, and the same effect of enhancing the alias component removing ability can be obtained even if the order is quadratic or higher.

### Third Embodiment

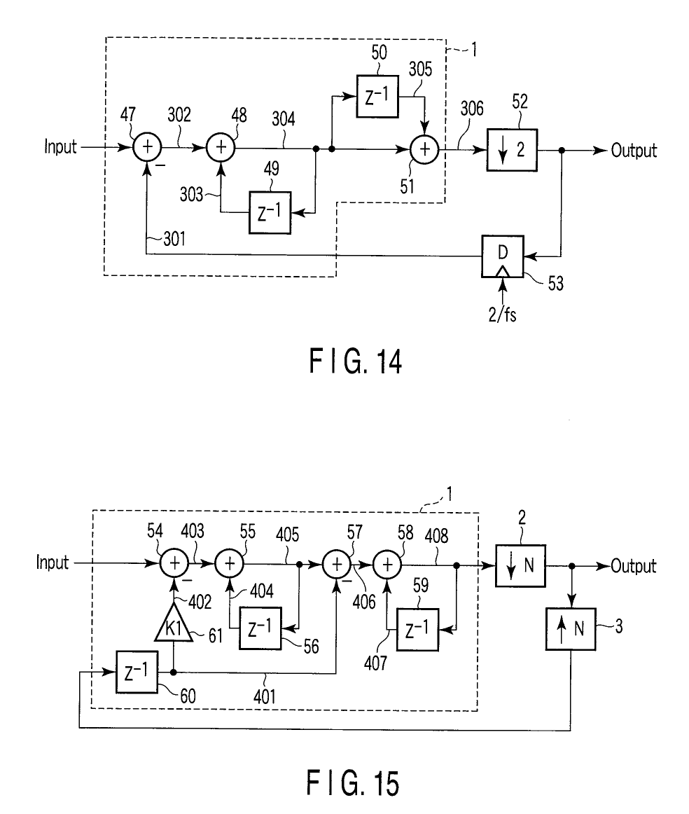

Next, a sample rate converter according to a third embodiment of the present invention will be explained. FIG. 14 is a block diagram showing a configuration of the sample rate converter. In the sample rate converter, the filter circuit 1 comprises an adder 47, an adder 48, a delay unit 49, a delay unit 50 and an adder 51. In addition, the sample rate converter comprises a downsampler circuit 52 and a D flip-flop circuit 53, which forms a feedback loop circuit.

The adder 47 subtracts a delay signal 301 obtained by inputting the feedback signal from the downsampler circuit 52 via the D flip-flop circuit 53, from the input signal sampled at the frequency fs, and outputs the subtraction result as a synthesized signal 302.

The adder 48 adds the synthesized signal 302 and a delay signal 303 obtained by delaying a synthesized signal 304 to be output from the adder 48 by the delay unit 49, and outputs the addition result as the synthesized signal 304.

The adder 51 adds the synthesized signal 304 and a delay signal 305 obtained by delaying the synthesized signal 304 by the delay unit 50, and outputs the addition result as the synthesized signal 306. The delay unit 49 and the delay circuit 50 delay the input signal by one sample. The output of the delay unit 49 may be used as the delay signal 305 by the adder 51 without using the delay unit 50.

The downsampler circuit 52 inputs the synthesized signal 306 which is the output of the filter circuit 1, and downsamples the input signal to decimate the signal sequence such that the sample rate becomes fs/2.

The D flip-flop circuit 53 serves as an upsampler circuit and an interpolation filter circuit by sampling the output of the downsampler circuit 52 at a clock of 2/fs. In addition, the D flip-flop circuit 53 also serves as a delay unit which delays the feedback signal by delaying the sample edge by 1 clock (i.e. reversing the phase of the clock of the downsampler circuit 52) at 1/fs sample rate.

By thus forming the sample rate converter, the alias component is generated in the output signal at the time of downsampling in the downsampler circuit 52. The alias component is suppressed in accordance with the characteristic of the filter circuit 1. Therefore, the alias component can be removed while making the desired signal characteristic substantially flat, by using the characteristic of the primary integrator which inserts a pole into a DC point as the characteristic of the filter circuit 1.

In addition, in the sample rate converter having the above-described configuration, since the D flip-flop circuit 53 is provided in the feedback loop as the interpolation filter circuit, amplitude attenuation in a high-pass portion can be improved. The order of the filter circuit 1 shown in FIG. 14 is set to be quadratic for simple explanation, and the same effect of enhancing the alias component removing ability can be obtained even if the order is quadratic or higher.

Since the functions of the upsampler circuit 44, the interpolation filter circuit 36 and the delay unit 42 shown in FIG. 13 are implemented by the D flip-flop circuit 53, the circuit configuration can be simplified and the circuit area can be reduced.

### Fourth Embodiment

Next, a sample rate converter according to a fourth embodiment will be described. The sample rate converter is formed by making the filter circuit shown in FIG. 1 have a quadratic filter characteristic as shown in FIG. 15.

In the sample rate converter, the filter circuit 1 comprises an adder 54, an adder 55, a delay unit 56, an adder 57, an adder 58, a delay unit 59, a delay unit 60, and a multiplier 61. In addition, the sample rate converter comprises the downsampler circuit 2 and the upsampler circuit 3 shown in FIG. 1.

The feedback signal from the upsampler circuit 3 is delayed by the delay unit 60 and output as a delay signal 401. The delay signal 401 is output to the adder 57, and is multiplied by coefficient k₁ in the multiplier 61 and output to the adder 54 as a signal 402.

The adder 54 subtracts the signal 402 from the input signal sampled at the frequency fs, and outputs the subtraction result as a synthesized signal 403.

The adder 55 adds the synthesized signal 403 and a delay signal 404 obtained by delaying a synthesized signal 405 to be output from the adder 55 by the delay unit 56, and outputs the addition result as the synthesized signal 405.

The adder 57 subtracts the delay signal 401 delayed by the delay unit 60, from the synthesized signal 405, and outputs the subtraction result as a synthesized signal 406.

The adder 58 adds the synthesized signal 406 and a delay signal 407 obtained by delaying the synthesized signal 408 output from the adder 58 by the delay unity 59, and outputs the addition result as a synthesized signal 408. The delay unit 56, the delay circuit 59 and the delay unit 60 delay the input signal by one sample.

The downsampler circuit 2 inputs a synthesized signal 408 which is the output of the filter circuit 1, and downsamples the sample rate of the synthesized signal to fs/N by executing downsampling to decimate number N−1 of data elements per N samples (where N represents an integer equal to or greater than 2), for the signal 408, and outputs the downsampled signal to the upsampler circuit 3 and a circuit of a subsequent stage (not shown).

The upsampler circuit 3 raises again the sample rate reduced by the downsampler circuit 2 to fs by executing upsampling to insert number N−1 of zero data elements between the sample value data, for the downsampled signal of sample rate fs/N, and outputs the signal to the filter circuit 1 as a feedback signal.

Thus, the filter circuit 1 uses two feedback signals to implement the quadratic filter characteristic, multiplies one of the feedback signals by coefficient k₁, and uses the output of multiplication as the feedback signal. For this reason, the same filter characteristic as that of the quadratic sinc function can be obtained by appropriately setting the value of rate N for downsampling and upsampling and the coefficient k₁.

Therefore, since the sample rate converter comprises the filter circuit 1 having the same filter characteristic as that of the quadratic sinc function, the alias component removing ability can be further enhanced as compared with the sample rate converter shown in FIG. 3 and the sample rate converter can be applied to a system which requires a high alias component removing ratio.

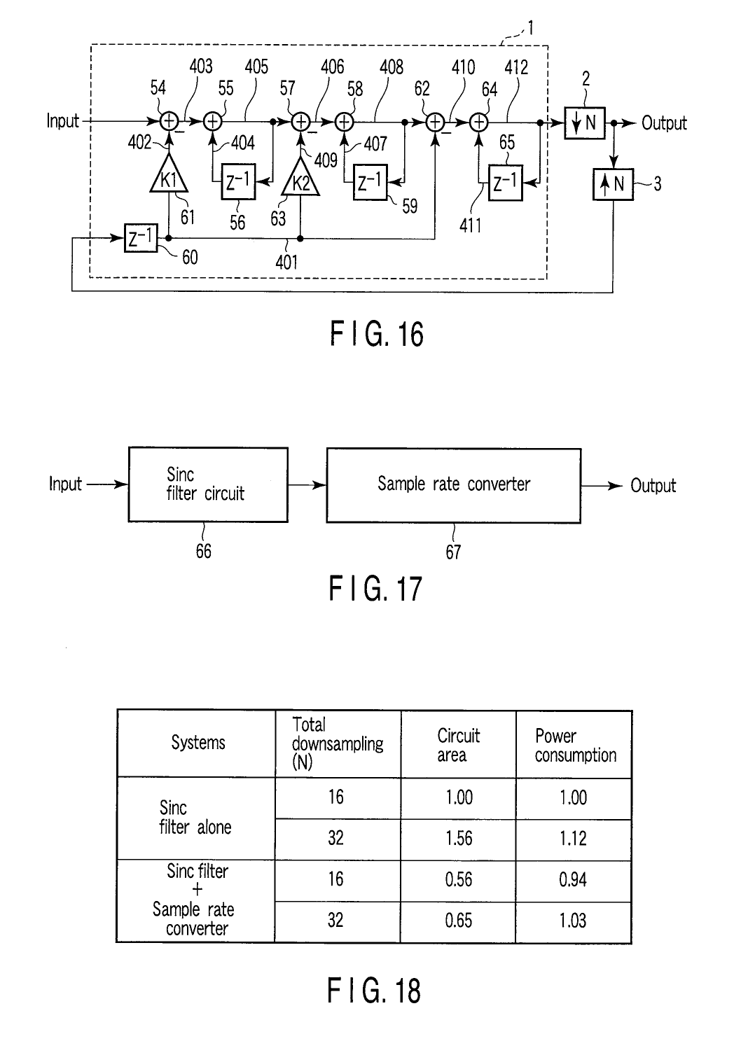

In the sample rate converter shown in FIG. 15, the filter characteristic of the filter circuit 1 is the quadratic filter characteristic but may be a cubic filter characteristic. An example thereof is shown in FIG. 16.

In the sample rate converter, the filter circuit 1 comprises the adder 54, the adder 55, the delay unit 56, the adder 57, the adder 58, the delay unit 59, the delay unit 60, the multiplier 61, an adder 62, a multiplier 63, an adder 64 and a delay unit 65. In addition, the sample rate converter comprises the downsampler circuit 2 and the upsampler circuit 3 shown in FIG. 1.

The feedback signal from the upsampler circuit 3 is delayed by the delay unit 60 and output as the delay signal 401. The delay signal 401 is output to the adder 62, and is multiplied by coefficient k₁ in the multiplier 61 and output to the adder 57 as a signal 409.

The adder 54 subtracts the signal 402 from the input signal sampled at the frequency fs, and outputs the subtraction result as the synthesized signal 403.

The adder 55 adds the synthesized signal 403 and the delay signal 404 obtained by delaying the synthesized signal 405 to be output from the adder 55 by the delay unit 56, and outputs the addition result as the synthesized signal 405.

The adder 57 subtracts the signal 409 from the synthesized signal 405, and outputs the subtraction result as the synthesized signal 406.

The adder 58 adds the synthesized signal 406 and the delay signal 407 obtained by delaying the synthesized signal 408 output from the adder 58 by the delay unity 59, and outputs the addition result as the synthesized signal 408.

The adder 62 subtracts the delay signal 401 from the synthesized signal 408, and outputs the subtraction result as the synthesized signal 408.

The adder 64 adds the synthesized signal 410 and the delay signal 411 obtained by delaying the synthesized signal 412 output from the adder 64 by the delay unity 65, and outputs the addition result as the synthesized signal 412. The delay unit 56, the delay circuit 59, the delay unit 60 and the delay unit 65 delay the input signal by one sample.

The downsampler circuit 2 inputs the synthesized signal 412 which is the output of the filter circuit 1, and downsamples the sample rate of the synthesized signal to fs/N by executing downsampling to decimate number N−1 of data elements per N samples (where N represents an integer equal to or greater than 2), for the signal 412, and outputs the downsampled signal to the upsampler circuit 3 and a circuit of a subsequent stage (not shown).

The upsampler circuit 3 raises again the sample rate reduced by the downsampler circuit 2 to fs by executing upsampling to insert number N−1 of zero data elements between the sample value data, for the downsampled signal of sample rate fs/N, and outputs the signal to the filter circuit 1 as a feedback signal.

Thus, the filter circuit 1 uses three feedback signals to implement the cubic filter characteristic, multiplies one of the feedback signals by coefficient k₁, multiplies another one by coefficient k₂, and uses each of them as the feedback signal. For this reason, the same filter characteristic as that of the cubic sinc function can be obtained by appropriately setting the value of rate N for downsampling and upsampling and the coefficients k₁ and k₂.

Therefore, since the sample rate converter comprises the filter circuit 1 having the same filter characteristic as that of the cubic sinc function, the alias component removing ability can be further enhanced as compared with the sample rate converter shown in FIG. 3 and the sample rate converter can be applied to a system which requires a high alias component removing ratio.

On a quartic or higher-order filter, the same characteristic as that of the sinc function can be implemented by appropriately multiplying the feedback signal by a coefficient in the same manner as that shown in FIG. 15 or FIG. 16.

The present invention is not limited to the embodiments described above but the constituent elements of the invention can be modified in various manners without departing from the spirit and scope of the invention. Various aspects of the invention can also be extracted from any appropriate combination of a plurality of constituent elements disclosed in the embodiments. Some constituent elements may be deleted in all of the constituent elements disclosed in the embodiments. The constituent elements described in different embodiments may be combined arbitrarily.

For example, in the above-described embodiments, one sample rate converter is employed, but a plurality of sample rate converters may be connected serially.

As shown in FIG. 17, for example, the conventionally employed sinc-type filter circuit 66 and the sample rate converter 67 corresponding to any one of the sample rate converters described in the first to fourth embodiments are connected serially.

The conventional sinc-type filter circuit has a problem that when a high downsampling ratio is implemented, the power consumption is not increased but the circuit area is increased. On the other hand, in the sample rate converter of the present invention, the circuit area can be reduced but the power consumption may be increased to implement a high downsampling ratio.

To solve this, the conventional sinc-type filter circuit 66 which is advantageous for the power consumption is arranged as a prior-step circuit and the circuit of the present invention is arranged as a subsequent-step circuit as shown in FIG. 17. In such a configuration, the circuit area becomes smaller and a circuit of small power consumption can be implemented as compared with the circuit which implements a high downsampling ratio with the conventional sinc-type filter alone. The order of the sinc-type filter circuit 66 in the prior step is set to be the same as the order of the sample rate converter 67 in the subsequent step.

FIG. 18 shows the effect in the small power consumption and small area. In FIG. 18, the power consumption and the circuit area in a case of employing the sinc-type filter circuit 66 alone and those in a case of employing a combination of the sinc-type filter circuit 66 and the sample rate converter 67 are compared. In this example, the circuit area of the sinc-type filter circuit is set at 1 when the total downsampling amount is 16, and the power consumption of the sinc-type filter circuit is set at 1 when the total downsampling amount is 16.

In the above-described embodiments, the output of the oversampling-type A/D converter is subjected to sample rate conversion. However, the present invention is not limited to this, but can be applied widely and generally to sample rate conversion of the digital signal.

In addition, the input signal input to the filter circuit of the embodiments is sampled with the frequency fs. This input signal is converted into a digital signal by, for example, a delta-sigma converter which converts an analog signal into a digital signal. The order of the transfer function of the filter function may be set to be equal to or higher than the order of the delta-sigma converter.

The present invention can also be otherwise variously modified within a scope which does not depart from the gist of the present invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A sample rate converter comprising:
a synthesizing unit which synthesizes an input signal sampled with frequency fs with a feedback signal of the frequency fs, in a frequency band from 0 to fs/N (where N indicates a natural number), with a gain greater than at least 1, to generate a synthesized signal;
a downsampler which downsamples the synthesized signal to obtain an output signal of sample rate fs/N; and
an upsampler which upsamples the output signal to generate the feedback signal.

2. The sample rate converter according to claim 1, wherein the synthesizing unit comprises:
a first delay unit which delays the feedback signal to generate a first delay signal;
a subtracter which subtracts the first delay signal from the input signal to generate a subtraction signal;
an adder which adds the subtraction signal to a second delay signal to generate the synthesized signal; and
a second delay unit which delays the synthesized signal to generate the second delay signal.

3. The sample rate converter according to claim 1, wherein the synthesizing unit comprises:
a first delay unit which delays the feedback signal to generate a first delay signal;
a divider which divides the first delay signal to generate a division signal;
a subtracter which subtracts the division signal from the input signal to generate a subtraction signal;
a first adder which adds the subtraction signal to a second delay signal to generate an addition signal;
a second delay unit which delays the addition signal to generate a second delay signal; and
a second adder which adds the addition signal to the second delay signal to generate the synthesized signal.

4. The sample rate converter according to claim 1, wherein the synthesizing unit comprises:
a first delay unit which delays the feedback signal to generate a first delay signal;
a first subtracter which subtracts the first delay signal from the input signal to generate a first subtraction signal;
a first adder which adds the first subtraction signal to a second delay signal to generate a first addition signal;
a second delay unit which delays the first addition signal to generate the second delay signal; and
a second subtracter which subtracts the first delay signal from the first addition signal to generate a second subtraction signal;
a second adder which adds the second subtraction signal to a third delay signal to generate the synthesized signal; and
a third delay unit which delays the synthesized signal to generate the third delay signal.

5. The sample rate converter according to claim 1, wherein the synthesizing unit comprises:
a first delay unit which delays the feedback signal to generate a first delay signal;
a multiplier which multiplies the first delay signal by a preset coefficient;
a first subtracter which subtracts the first delay signal multiplied by the coefficient from the input signal to generate a first subtraction signal;
a first adder which adds the first subtraction signal to a second delay signal to generate a first addition signal;
a second delay unit which delays the first addition signal to generate the second delay signal; and
a second subtracter which subtracts the first delay signal from the first addition signal to generate a second subtraction signal;
a second adder which adds the second subtraction signal to a third delay signal to generate the synthesized signal; and
a third delay unit which delays the synthesized signal to generate the third delay signal.

6. The sample rate converter according to claim 1, wherein the synthesizing unit comprises:
a first delay unit which delays the feedback signal to generate a first delay signal;
a first multiplier which multiplies the first delay signal by a preset first coefficient;
a first subtracter which subtracts the first delay signal multiplied by the first coefficient from the input signal to generate a first subtraction signal;
a first adder which adds the first subtraction signal to a second delay signal to generate a first addition signal;
a second delay unit which delays the first addition signal to generate the second delay signal;
a second multiplier which multiplies the first delay signal by a preset second coefficient;
a second subtracter which subtracts the first delay signal multiplied by the second coefficient from the first addition signal to generate a second subtraction signal;
a second adder which adds the second subtraction signal to a third delay signal to generate a second addition signal;
a third delay unit which delays the second addition signal to generate the third delay signal;
a third subtracter which subtracts the first delay signal from the second addition signal to generate a third subtraction signal;
a third adder which adds the third subtraction signal to a fourth delay signal to generate the synthesized signal; and
a fourth delay unit which delays the synthesized signal to generate the fourth delay signal.

7. The sample rate converter according to claim 1, wherein the N is a natural number equal to or greater than 4.

8. The sample rate converter according to claim 1, further comprising an FIR filter which filters the input signal by multiplying the input signal by a window function,
wherein the synthesizing unit synthesizes the filtered input signal and the feedback signal.

9. The sample rate converter according to claim 1, further comprising an interpolator which executes an interpolation process for the feedback signal,
wherein the synthesizing unit generates the synthesized signal by synthesizing the input signal with the feedback signal subjected to the interpolation process, in the frequency band from 0 to fs/N (where N indicates a natural number), with the gain greater than at least 1.

10. The sample rate converter according to claim 9, wherein the interpolator executes the interpolation process by executing filtering of multiplying the feedback signal with a window function.

11. The sample rate converter according to claim 9, wherein the interpolator comprises:
a delay unit which delays the feedback signal to generate a delay signal; and
a adder which adds the feedback signal to the feedback signal to generate the feedback signal subjected to the interpolation process.

12. The sample rate converter according to claim 9, wherein the interpolator comprises a D-type flip-flop which operates with frequency N/fs and generates the feedback signal subjected to the interpolation process from the upsampled output signal, and
the synthesizing unit comprises:
a subtracter which subtracts the feedback signal subjected to the interpolation process from the input signal to generate a subtraction signal;
a first adder which adds the subtraction signal to a first delay signal to generate a addition signal;
a first delay unit which delays the addition signal to generate the first delay signal;
a second delay unit which delays the addition signal to generate a second delay signal; and
a second adder which adds the addition signal to the second delay signal to generate the synthesized signal.

13. The sample rate converter according to claim 9, wherein the interpolator comprises a D-type flip-flop which operates with frequency N/fs and generates the feedback signal subjected to the interpolation process from the upsampled output signal, and
the synthesizing unit comprises:
a subtracter which subtracts the feedback signal subjected to the interpolation process from the input signal to generate a subtraction signal;
a first adder which adds the subtraction signal to a delay signal to generate a addition signal;
a delay unit which delays the addition signal to generate the delay signal; and
a second adder which adds the addition signal to the delay signal to generate the synthesized signal.

14. The sample rate converter according to claim 9, further comprising an FIR filter which filters the input signal by multiplying the input signal by a window function,
wherein the synthesizing unit synthesizes the filtered input signal with the feedback signal subjected to the interpolation process.

15. A serial connection type sample rate converter wherein a plurality of sample rate converters identical with the sample rate converter according to claim 1 are connected serially.
